(19) United States
(12) Patent Application Publication
(10) Pub. No.: US 2025/0014974 A1
(43) Pub. Date: Jan. 9, 2025

(54) SEMICONDUCTOR PACKAGE

(71) Applicant: SAMSUNG ELECTRONICS CO., LTD, Suwon-si (KR)

(72) Inventors: Jing Cheng LIN, Suwon-si (KR); Youngkun JEE, Suwon-si (KR)

(73) Assignee: SAMSUNG ELECTRONICS CO., LTD, Suwon-si (KR)

(21) Appl. No.: 18/750,209

(22) Filed: Jun. 21, 2024

(30) Foreign Application Priority Data
Jul. 3, 2023 (KR) 10-2023-0085985

(51) Int. Cl. H01L 23/498; H01L 21/768; H01L 23/00; H01L 23/31; H01L 25/16; H10B 80/00

(52) U.S. Cl. CPC H01L 23/49811; H01L 21/76816; H01L 23/3128; H01L 23/49827; H01L 23/49838; H01L 23/49894; H01L 24/03; H01L 24/13; H01L 25/165; H10B 80/00; H01L 24/05; H01L 2224/03845; H01L 2224/05568; H01L 2224/0557; H01L 2224/16238; H01L 2924/1431

(57) ABSTRACT

A semiconductor package and a method of manufacturing the semiconductor package are provided. A method includes: forming a seed layer; forming a first photoresist pattern on the seed layer; forming a metal pad on the seed layer by using the first photoresist pattern; forming a second photoresist pattern on the seed layer; forming a conductive post on the seed layer by using the second photoresist pattern; providing, on the metal pad, a first semiconductor chip on which a conductive pillar and an insulating material layer surrounding a sidewall of the conductive pillar are formed; bonding the first semiconductor chip to the metal pad by using a connection terminal; forming a first molding layer surrounding the first semiconductor chip; removing the connection terminal and the metal pad; and forming a redistribution structure connected to the conductive pillar.

### CROSS-REFERENCE TO RELATED APPLICATION

This application is based on and claims priority under 35 U.S.C. § 119 to Korean Patent Application No. 10-2023-0085985, filed on Jul. 3, 2023, in the Korean Intellectual Property Office, the disclosure of which is incorporated by reference herein in its entirety.

### BACKGROUND

### 1. Field

Embodiments of the present disclosure relate to a semiconductor package. More specifically, embodiments of the present disclosure relate to a fan-out semiconductor package.

### 2. Description of Related Art

Size and weight reduction of electronic components mounted on electronic products are required according to the development of the electronic industry and the needs of users. In order to meet this demand, a semiconductor package mounted on an electronic component includes a highly integrated semiconductor chip. Therefore, semiconductor packages having connection terminals with connection reliability have been designed for highly integrated semiconductor chips with an increased number of connection terminals for input/output (I/O). For example, in order to reduce interference between connection terminals, fan-out semiconductor packages having an increased distance between the connection terminals have been developed.

### SUMMARY

Embodiments of the present disclosure provide a semiconductor package with improved reliability and a method of manufacturing the semiconductor package.

According to embodiments of the present disclosure, a method of manufacturing a semiconductor package is provided. The method includes: forming a seed layer; forming a first photoresist pattern on the seed layer; forming a metal pad on the seed layer by using the first photoresist pattern; forming a second photoresist pattern on the seed layer; forming a conductive post on the seed layer by using the second photoresist pattern; providing, on the metal pad, a first semiconductor chip on which a conductive pillar and an insulating material layer surrounding a sidewall of the conductive pillar are formed; bonding the first semiconductor chip to the metal pad by using a connection terminal; forming a first molding layer surrounding the first semiconductor chip; removing the connection terminal and the metal pad; and forming a redistribution structure connected to the conductive pillar.

According to embodiments of the present disclosure, a semiconductor package is provided. The semiconductor package includes: a redistribution structure including redistribution lines and redistribution vias; a first semiconductor chip on the redistribution structure; a conductive post separated from the first semiconductor chip in a horizontal direction and on the redistribution structure; a first molding layer surrounding the first semiconductor chip and the conductive post in the horizontal direction and on the redistribution structure; conductive pillars on a lower surface of the first semiconductor chip, the conductive pillars respectively metal-metal-bonded to uppermost portions of some of the redistribution vias; and an insulating material layer surrounding sidewalls of the conductive pillars.

According to embodiments of the present disclosure, a method of manufacturing a semiconductor package is provided. The method includes: forming a seed layer; forming a first photoresist pattern on the seed layer; forming a metal pad on the seed layer by using the first photoresist pattern; forming a second photoresist pattern on the seed layer; forming a conductive post on the seed layer by using the second photoresist pattern; removing the seed layer and providing, on the metal pad, a first semiconductor chip including a lower surface on which a conductive pillar and an insulating material layer surrounding a sidewall of the conductive pillar are formed; bonding the conductive pillar to the metal pad by performing a solder reflow process by using a connection terminal between the conductive pillar and the metal pad; forming a first molding layer surrounding the first semiconductor chip; planarizing an upper surface of the first molding layer; removing the connection terminal and the metal pad by performing a planarization process; and forming a redistribution structure that is metal-metal-bonded to the conductive pillar.

### BRIEF DESCRIPTION OF DRAWINGS

Embodiments will be more clearly understood from the following detailed description taken in conjunction with the accompanying drawings in which:

FIG. 1 is a cross-sectional view illustrating a semiconductor package according to embodiments;

FIG. 2 is an enlarged cross-sectional view of a region EX of FIG. 1;

FIG. 3 is an enlarged cross-sectional view of a region corresponding to the region EX of FIG. 1;

FIG. 4 is another enlarged cross-sectional view of a region corresponding to the region EX of FIG. 1;

FIG. 5 is a cross-sectional view illustrating a semiconductor package according to embodiments;

FIG. 6 is a cross-sectional view illustrating a semiconductor package according to embodiments;

FIGS. 7A to 7D are cross-sectional views illustrating a method of manufacturing a semiconductor package, according to embodiments; and

FIGS. 8A to 8P are cross-sectional views illustrating a method of manufacturing a semiconductor package, according to embodiments.

### DETAILED DESCRIPTION

Hereinafter, non-limiting example embodiments are described in detail with reference to the accompanying drawings. The same reference numerals are used for the same components in the drawings, and redundant descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

It will be also understood that, even if a certain step or operation of manufacturing an apparatus or structure is described later than another step or operation, the step or operation may be performed later than the other step or operation unless the other step or operation is described as being performed after the step or operation. Further, functions, operations or steps described in a particular block may occur in a different way from a flow described in a flowchart. For example, two consecutive blocks may be performed simultaneously, or the blocks may be performed in reverse according to related functions, operations or steps.

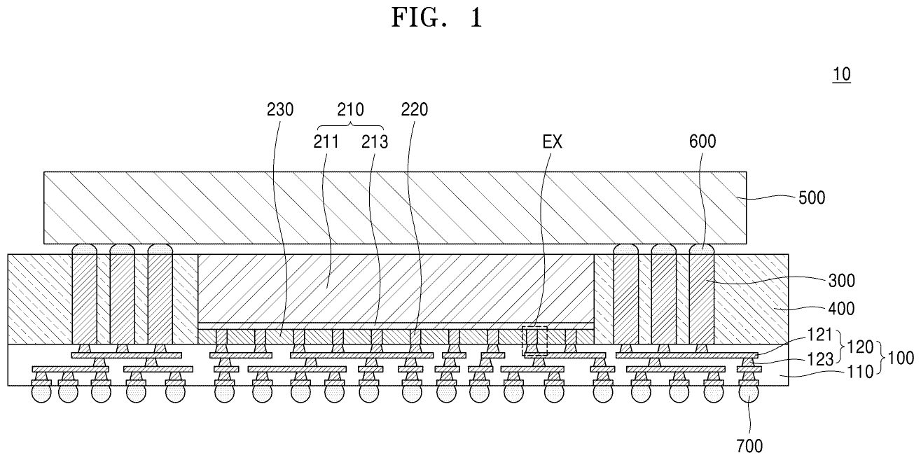

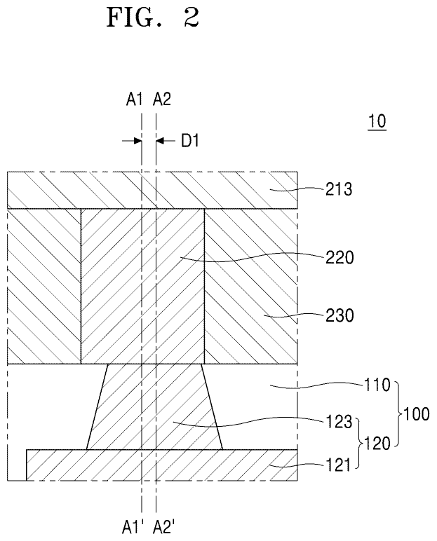

FIG. 1 is a cross-sectional view illustrating a semiconductor package 10 according to embodiments. FIG. 2 is an enlarged cross-sectional view of a region EX of FIG. 1.

Referring to FIGS. 1 and 2, the semiconductor package 10 may include a redistribution structure 100, a first semiconductor chip 210, conductive posts 300, a first molding layer 400, and a second semiconductor chip 500.

The redistribution structure 100 may be a substrate on which the first semiconductor chip 210 is mounted. The redistribution structure 100 may include a redistribution insulating layer 110 and a redistribution pattern 120. Hereinafter, unless otherwise defined, a direction parallel to an upper surface of the redistribution structure 100 is a horizontal direction, and a direction perpendicular to the upper surface of the redistribution structure 100 is a vertical direction.

The redistribution insulating layer 110 may cover the redistribution pattern 120. The redistribution insulating layer 110 may include a plurality of insulating layers stacked in the vertical direction or a single insulating layer. The redistribution insulating layer 110 may include, for example, photo imageable dielectric (PID) or photosensitive polyimide (PSPI).

The redistribution pattern 120 may include redistribution lines 121 and redistribution vias 123. The redistribution lines 121 may each extend in the horizontal direction along at least one from among an upper surface and a lower surface of each of insulating layers constituting the redistribution insulating layer 110. The redistribution lines 121 may include a plurality of layers. For example, the redistribution lines 121 may include a plurality of layers at different vertical levels. Although FIG. 1 illustrates that the redistribution lines 121 include three layers at different vertical levels, embodiments of the present disclosure are not limited thereto. For example, the redistribution lines 121 may also include two or less layers or four or more layers. The redistribution vias 123 may each connect redistribution lines 121 at different vertical levels to each other. In one embodiment, the redistribution vias 123 may each have a tapered shape in which a length in a horizontal direction increases as a distance from the first semiconductor chip 210 increases. The redistribution pattern 120 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

The first semiconductor chip 210 may be on the redistribution structure 100. In embodiments, the first semiconductor chip 210 may be a memory chip or a logic chip. The memory chip may be, for example, a volatile memory chip, such as dynamic random access memory (DRAM) or static random access memory (SRAM), or a nonvolatile memory chip, such as phase-change random access memory (PRAM), magnetoresistive random access memory (MRAM), ferroelectric random access memory (FeRAM), or resistive random access memory (RRAM). Also, the logic chip may be, for example, a microprocessor, an analog device, or a digital signal processor.

The first semiconductor chip 210 may include a first semiconductor substrate 211 and a first wiring structure 213. The first semiconductor substrate 211 may be a group IV semiconductor, such as silicon (Si) or germanium (Ge), a group IV-IV compound semiconductor, such as silicon-germanium (SiGe) or silicon carbide (SiC), or a group III-V compound semiconductor, such as gallium arsenic (GaAs), indium arsenide (InAs), or indium phosphide (InP). The first semiconductor substrate 211 may include a conductive region, for example, a well doped with impurities. The first semiconductor substrate 211 may have various device isolation structures, such as a shallow trench isolation (STI) structure.

The first semiconductor substrate 211 may have a first active surface and a first inactive surface opposite to the first active surface. The first active surface of the first semiconductor substrate 211 may correspond to an upper surface of the first semiconductor substrate 211 facing the second semiconductor chip 500, and the inactive surface of the first semiconductor substrate 211 may correspond to a lower surface of the first semiconductor substrate 211 facing the redistribution structure 100.

The first active surface may include a plurality of individual devices of various types. The plurality of individual devices may include various micro electronic devices, for example, a metal-oxide-semiconductor filed effect transistor (MOSFET) such as a complementary metal-oxide semiconductor transistor (CMOS transistor), a system large scale integration (LSI), an image sensor such as a CMOS imaging sensor (CIS), a micro-electro-mechanical system (MEMS), an active element, and a passive element. The plurality of individual devices may be electrically connected to a conductive region of the first semiconductor substrate 211. Each of the plurality of individual devices may be electrically separated from other adjacent individual devices by a first insulating layer.

The first wiring structure 213 may be on a lower surface (that is, an inactive surface) of the first semiconductor substrate 211. The first wiring structure 213 may include a wiring insulating layer and a wiring pattern. Each of the wiring insulating layer and the wiring pattern has a structure substantially the same as or similar to the structure of each of the redistribution insulating layer 110 and the redistribution pattern 120 of the redistribution structure 100 described above, and may include a material substantially the same as or similar to the material of each of the redistribution insulating layer 110 and the redistribution patterns 120.

Conductive pillars 220 may arranged be between the redistribution structure 100 and the first semiconductor chip 210. Upper surfaces of the conductive pillars 220 are in contact with the wiring structure 213 of the first semiconductor chip 210, and lower surfaces of the conductive pillars 220 may be in contact with at least some redistribution vias 123 at an uppermost portion among the redistribution vias 123 of the redistribution structure 100. The conductive pillars 220 are in direct contact with the redistribution vias 123, and accordingly, the conductive pillars 220 may be respectively metal-metal-bonded to the redistribution vias 123. However, embodiments of the present disclosure are not limited thereto, and lower surfaces of the conductive pillars 220 may be respectively in contact with at least some redistribution lines 121 at an uppermost portion among the redistribution lines 121 of the redistribution structure 100. The conductive pillars 220 may electrically connect the first semiconductor chip 210 to the redistribution structure 100.

In one embodiment, a pitch between the conductive pillars 220 may be about 15 μm to about 100 μm. For example, the pitch between the conductive pillars 220 may be about 30 μm.

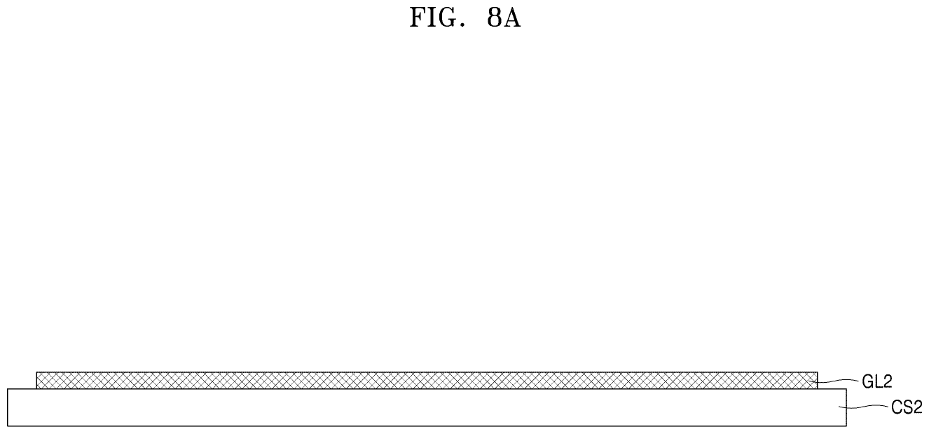

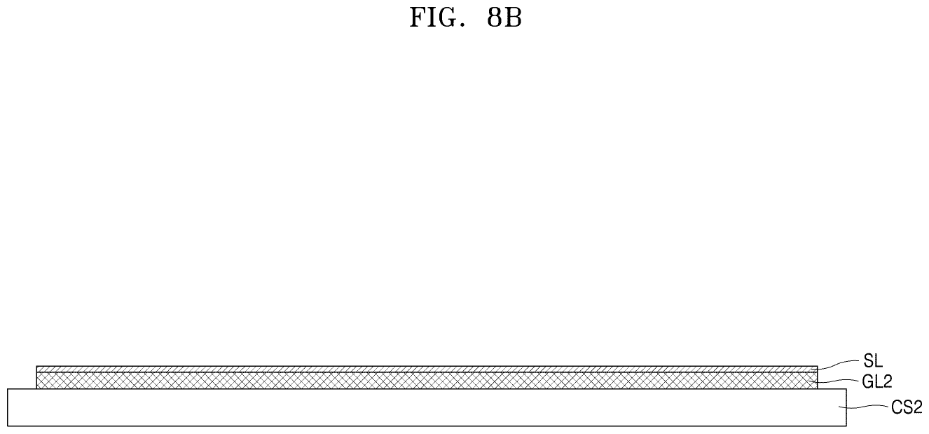

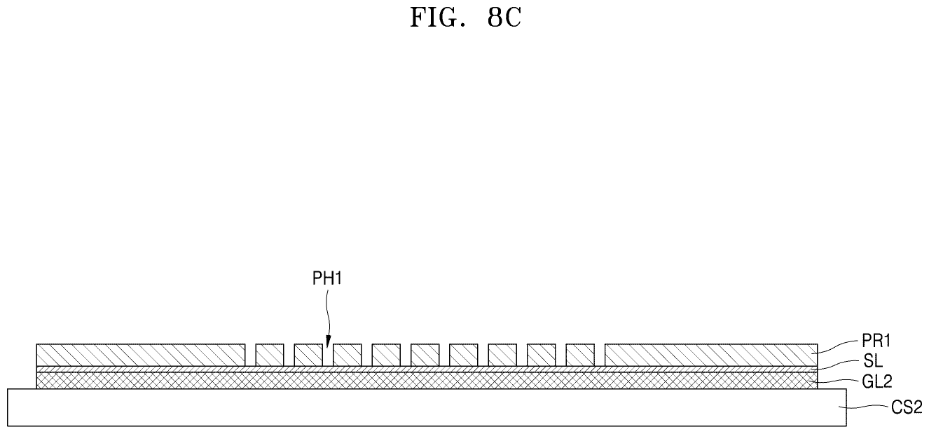

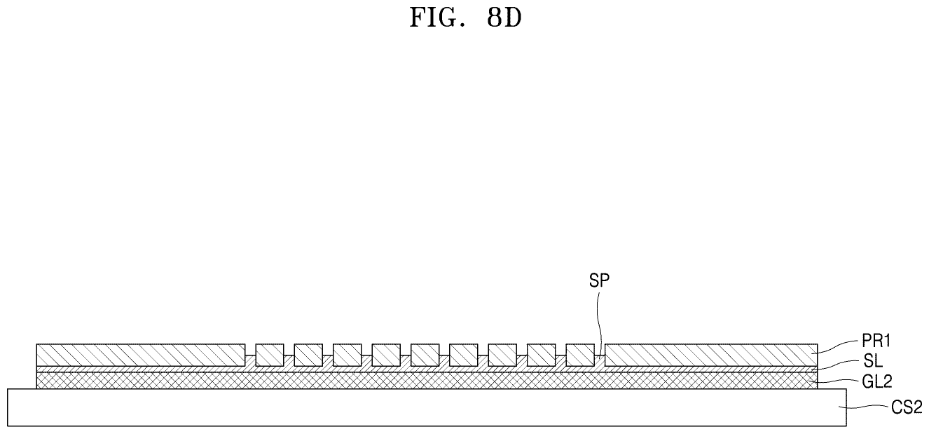

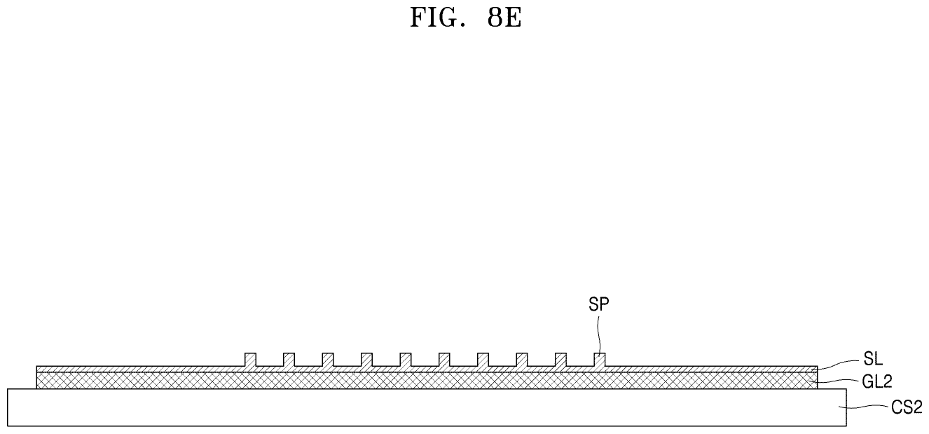

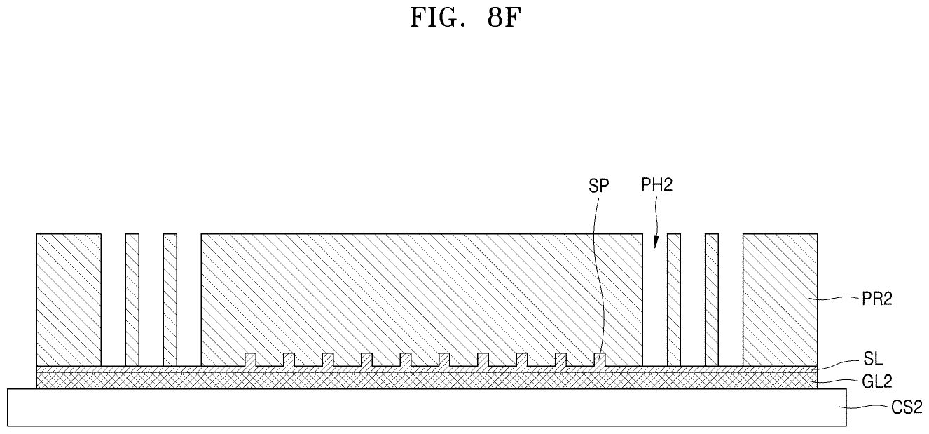

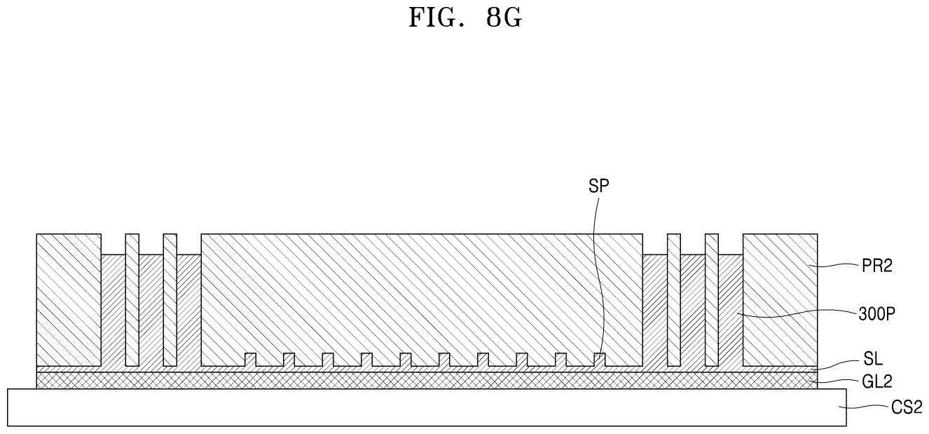

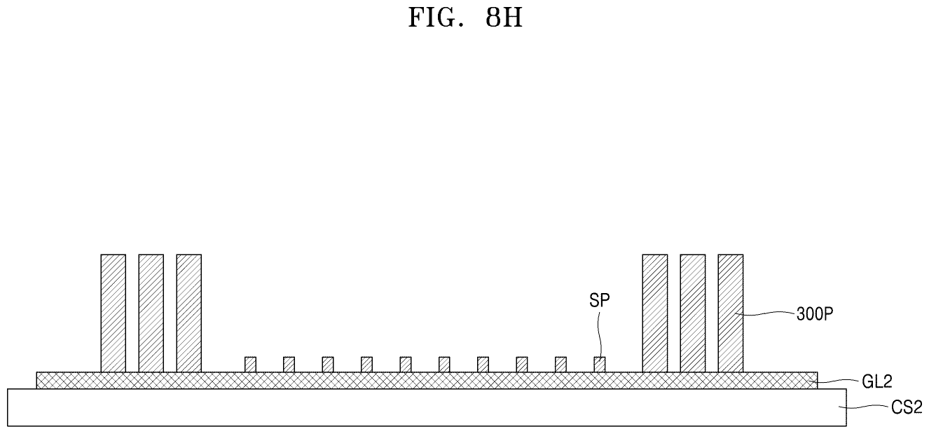

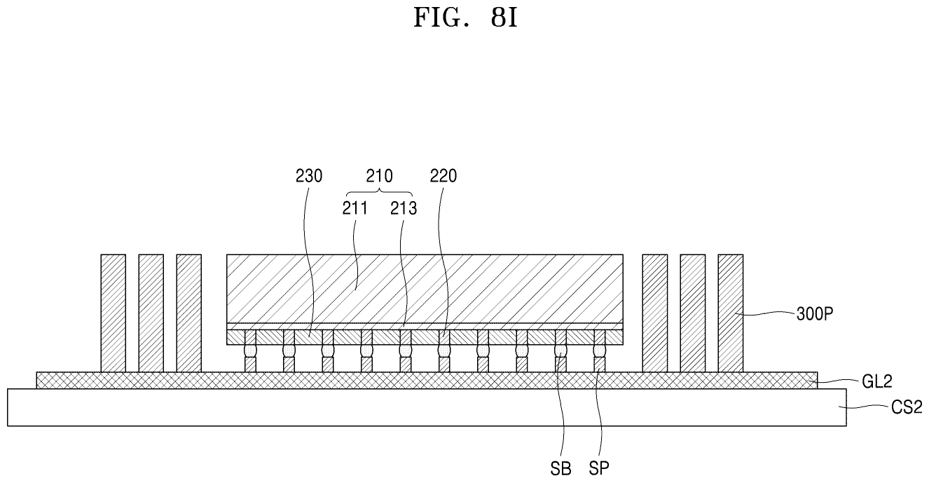

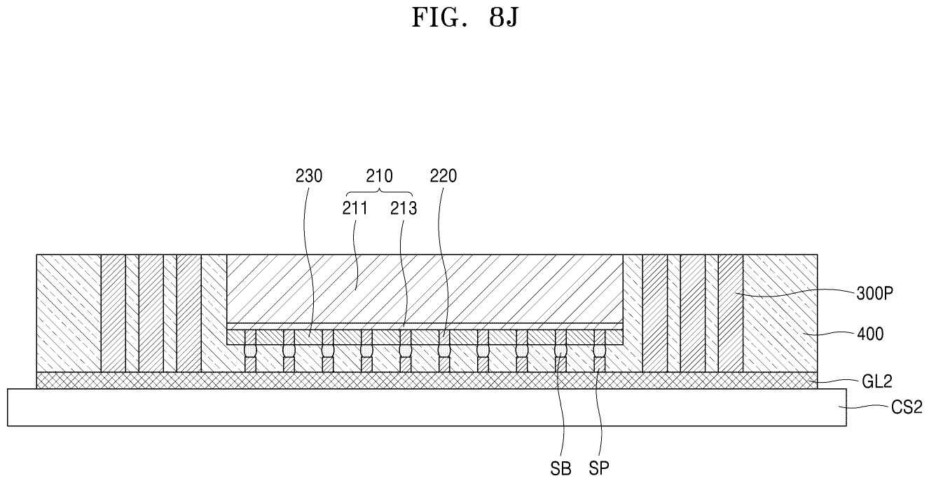

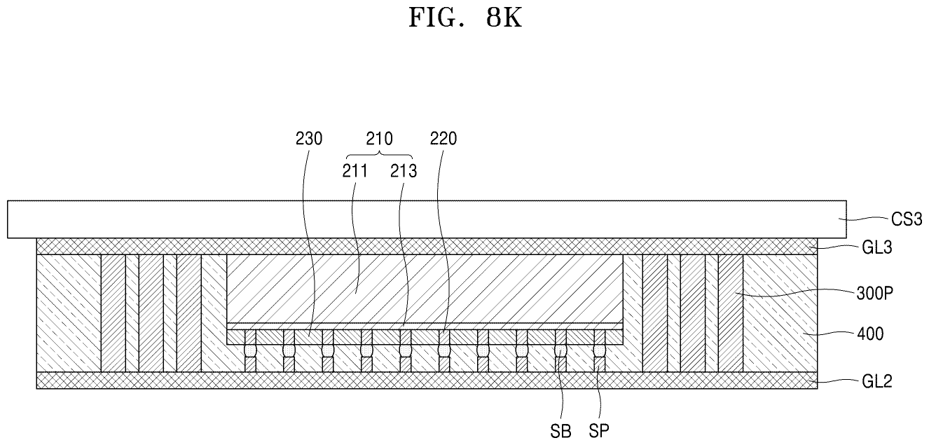

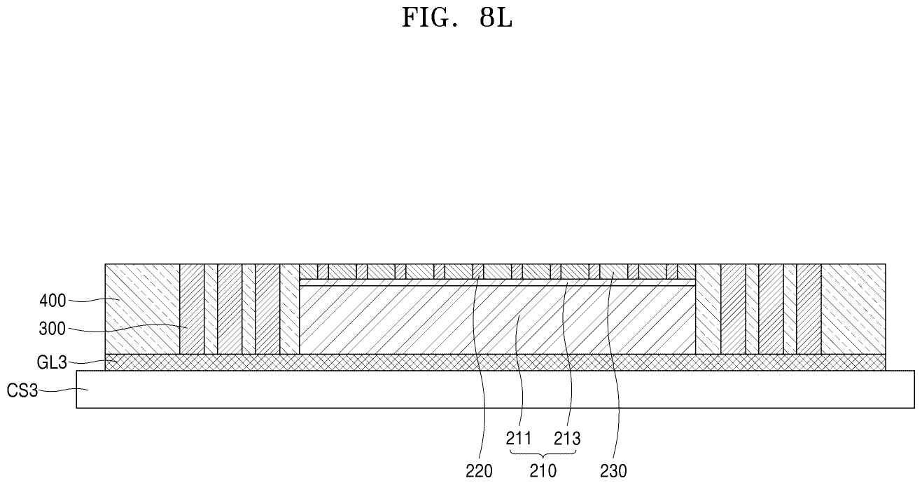

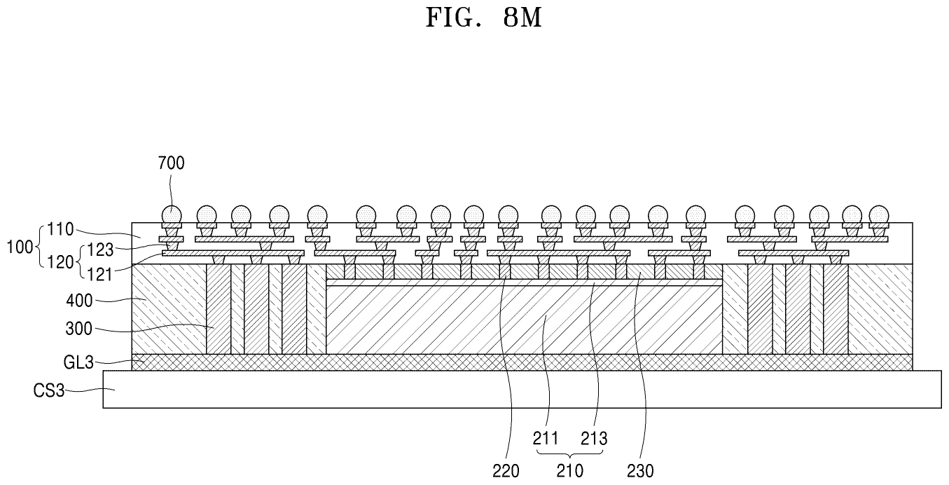

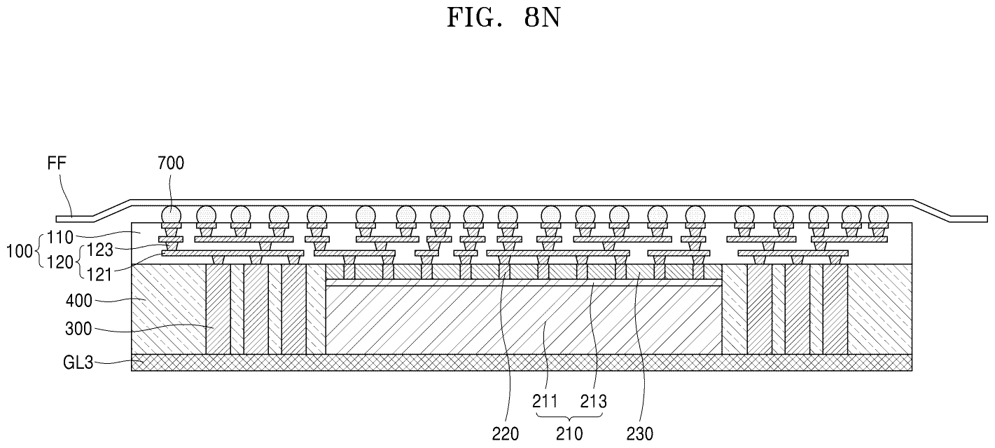

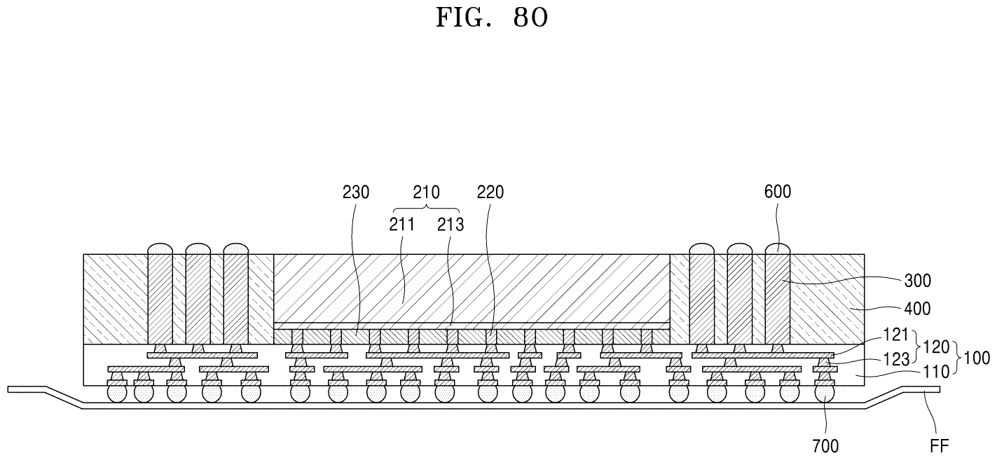

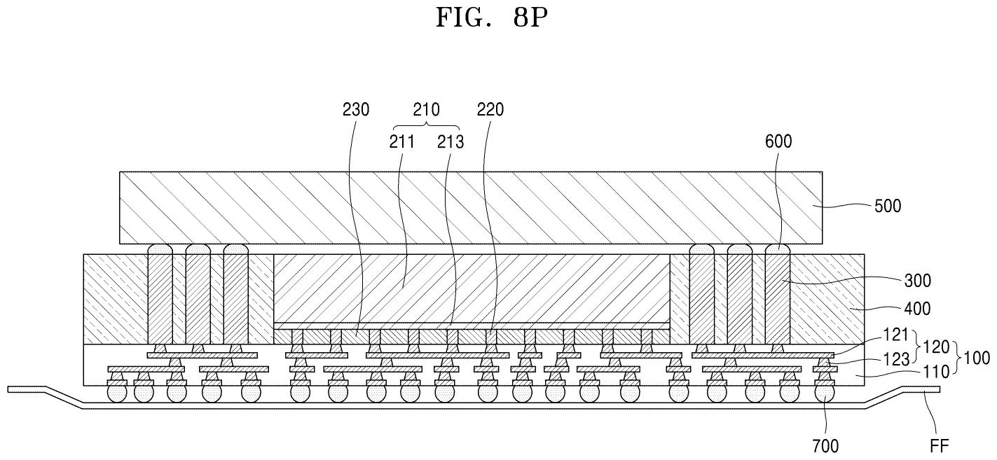

In one embodiment, a separation distance between the center of the conductive pillar 220 and the center of the redistribution via 123 in contact with the conductive pillar 220 may be about 0.3 μm to about 1 μm. For example, a separation distance between an imaginary line A1-A1′ passing through the center of the conductive pillar 220 and an imaginary line A2-A2′ passing through the center of the redistribution via 123 in contact with the conductive pillar 220 may be from about 0.3 μm to about 1 μm. This is because, in a manufacturing process of the semiconductor package 10 to be described below with reference to FIGS. 8A to 8P, the first semiconductor chip 210 is self-aligned by a solder reflow process, thereby being relatively accurately aligned in an intended position.

The conductive pillars 220 may each include a metal, such as copper, aluminum, tungsten, titanium, tantalum, indium, molybdenum, manganese, cobalt, tin, nickel, magnesium, rhenium, beryllium, gallium, or ruthenium, or an alloy thereof. In embodiments, the redistribution vias 123 and the conductive pillars 220 may include the same material. For example, the redistribution vias 123 and the conductive pillars 220 may include copper.

An insulating material layer 230 may be between the redistribution structure 100 and the first semiconductor chip 210 and may surround the conductive pillars 220. An upper surface of the insulating material layer 230 may be coplanar with upper surfaces of the conductive pillars 220, and a lower surface of the insulating material layer 230 may be coplanar with lower surfaces of the conductive pillars 220. The insulating material layer 230 may completely cover sidewalls of the conductive pillars 220. A horizontal area of the insulating material layer 230 may be substantially the same as a footprint of the first semiconductor chip 210. In embodiments, the insulating material layer 230 may include at least one selected from SiO₂, SiC, SiON, SiOC, SiCN, SiN, and SiOCN. For example, the insulating material layer 230 may be formed of SiO₂. The insulating material layer 230 may insulate the conductive pillars 220 on a lower surface of the first semiconductor chip 210 from each other. Accordingly, an electrical short circuit between adjacent conductive pillars 220 may be prevented.

The conductive posts 300 may be on the redistribution structure 100 to be separated from the first semiconductor chip 210 in the horizontal direction. For example, the first semiconductor chip 210 may be on a central region of the redistribution structure 100, and the conductive posts 300 may be in an edge region of the redistribution structure 100 to be separated from the first semiconductor chip 210 in the horizontal direction. Lower surfaces of the conductive posts 300 may be in contact with at least some redistribution vias 123 at an uppermost portion among the redistribution vias 123 of the redistribution structure 100. However, embodiments of the present disclosure are not limited thereto. For example, the lower surfaces of the conductive posts 300 may be in contact with at least some redistribution lines 121 at an uppermost portion among the redistribution lines 121 of the redistribution structure 100. Upper surfaces of the conductive posts 300 may be coplanar with an upper surface of the first semiconductor chip 210 and an upper surface of the first molding layer 400. The lower surfaces of the conductive posts 300 may be coplanar with the lower surfaces of the conductive pillars 220 and a lower surface of the first molding layer 400. The conductive posts 300 may electrically connect the redistribution structure 100 to the second semiconductor chip 500. The conductive posts 300 may each include, for example, a metal, such as copper, aluminum, tungsten, titanium, tantalum, indium, molybdenum, manganese, cobalt, tin, nickel, magnesium, rhenium, beryllium, gallium, or ruthenium, or an alloy thereof.

The first molding layer 400 may be on the redistribution structure 100. The first molding layer 400 may surround a side surface of the first semiconductor chip 210, a side surface of the insulating material layer 230, and side surfaces of the conductive posts 300. The first molding layer 400 may include, for example, an epoxy molding compound (EMC).

The second semiconductor chip 500 may be on the first semiconductor chip 210. A footprint of the second semiconductor chip 500 may be greater than a footprint of the first semiconductor chip 210. Accordingly, the second semiconductor chip 500 may vertically overlap the conductive posts 300 that are separated from the first semiconductor chip 210 in the horizontal direction. Connection terminals 600 may be between the conductive posts 300 and the second semiconductor chip 500. The connection terminals 600 may electrically connect the conductive posts 300 to the second semiconductor chip 500. The connection terminals 600 may be formed of, for example, solder.

In one embodiment, the second semiconductor chip 500 may be a memory chip or a logic chip. The memory chip may be, for example, a volatile memory chip, such as DRAM or SRAM, or a nonvolatile memory chip, such as PRAM, MRAM, FeRAM, or RRAM. Also, the logic chip may be, for example, a microprocessor, an analog device, or a digital signal processor. In embodiments, the first semiconductor chip 210 and the second semiconductor chip 500 may be semiconductor chips of different types. For example, the first semiconductor chip 210 may be a logic chip, and the second semiconductor chip 500 may be a memory chip. In other embodiments, the first semiconductor chip 210 and the second semiconductor chip 500 may be the same type of semiconductor chip. For example, the first semiconductor chip 210 and the second semiconductor chip 500 may be memory chips.

External connection terminals 700 may be on a lower surface of the redistribution structure 100. Some of the external connection terminals 700 may vertically overlap with the first semiconductor chip 210 and/or the second semiconductor chip 500, and the others of the external connection terminals 700 may not overlap vertically with the first semiconductor chip 210 and/or the second semiconductor chip 500. The external connection terminals 700 may each include, for example, a solder ball. The external connection terminals 700 may connect the semiconductor package 10 to an external device.

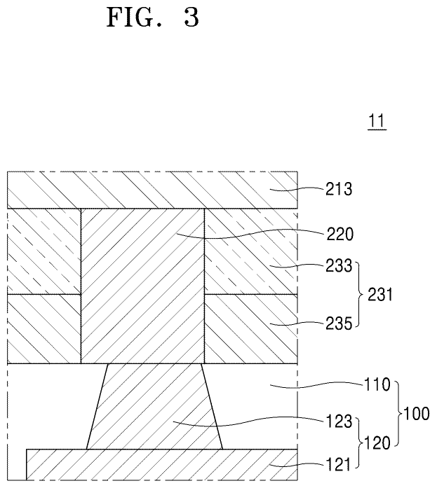

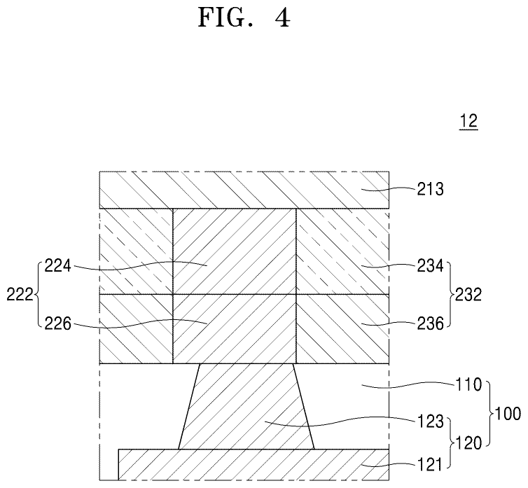

FIG. 3 is an enlarged cross-sectional view of a region corresponding to a region EX of FIG. 1. FIG. 4 is another enlarged cross-sectional view of a region corresponding to the region EX of FIG. 1. Configurations of a semiconductor package 11 illustrated in FIG. 3 and configurations of a semiconductor package 12 illustrated in FIG. 4 are similar to configurations of the semiconductor package 10 described with reference to FIGS. 1 and 2, and accordingly, the following will focus on differences therebetween.

Referring to FIGS. 1 and 3 together, the semiconductor package 11 may include the redistribution structure 100, the first semiconductor chip 210, the conductive posts 300, the first molding layer 400, and the second semiconductor chip 500.

The conductive pillar 220 may be between a first semiconductor chip 210 of the semiconductor package 11 and a redistribution structure 100 of the semiconductor package 11. An insulating material layer 231 may be between a first semiconductor chip 210 of the semiconductor package 11 and the redistribution structure 100 of the semiconductor package 11 and may surround the conductive pillar 220. In one embodiment, the insulating material layer 231 may include a first insulating material layer 233 and a second insulating material layer 235. The first insulating material layer 233 may refer to a part of the insulating material layer 231 which is relatively adjacent to the wiring structure 213 of the first semiconductor chip 210, and the second insulating material layer 235 may refer to the other part of the insulating material layer 231 which is relatively adjacent to the redistribution structure 100. The first insulating material layer 233 may surround a part of a sidewall of the conductive pillar 220 which is relatively adjacent to the wiring structure 213 of the first semiconductor chip 210, and the second insulating material layer 235 may surround the other part of the sidewall of the conductive pillar 220 which is relatively adjacent to the redistribution structure 100. In embodiments, the first insulating material layer 233 and the second insulating material layer 235 may each include at least one selected from SiO₂, SiC, SiON, SiOC, SiCN, SiN, and SiOCN. In embodiments, the first insulating material layer 233 and the second insulating material layer 235 may include different materials. For example, the first insulating material layer 233 may include SiO₂ and the second insulating material layer 235 may include SiN. Although FIG. 3 illustrates that the insulating material layer 231 includes two layers, embodiments of the present disclosure are not limited thereto. For example, the insulating material layer 231 may include three or more layers.

Referring to FIGS. 1 and 4 together, the semiconductor package 12 may include the redistribution structure 100, the first semiconductor chip 210, the conductive posts 300, the first molding layer 400, and the second semiconductor chip 500.

A conductive pillar 222 may be between a first semiconductor chip 210 of the semiconductor package 12 and a redistribution structure 100 of the semiconductor package 12. In embodiments, the conductive pillar 222 may include a first conductive pillar 224 and a second conductive pillar 226. The first conductive pillar 224 may refer to a part of the conductive pillar 222 which is relatively adjacent to the wiring structure 213 of the first semiconductor chip 210, and the second conductive pillar 226 may refer to the other part of the conductive pillar 222 which is relatively adjacent to the redistribution structure 100. An upper surface of the first conductive pillar 224 may be in contact with a wiring structure 213 of the first semiconductor chip 210, and a lower surface of the first conductive pillar 224 may be in contact with the second conductive pillar 226. A lower surface of the second conductive pillar 226 may be in contact with a redistribution via 123 of the redistribution structure 100. In embodiments, the first conductive pillar 224 and the second conductive pillar 226 may have the same horizontal area. In embodiments, the first conductive pillar 224 and the second conductive pillar 226 may each be formed of a metal, such as copper, aluminum, tungsten, titanium, tantalum, indium, molybdenum, manganese, cobalt, tin, nickel, magnesium, rhenium, or beryllium, gallium, or ruthenium, or an alloy thereof. In embodiments, the first conductive pillar 224 and the second conductive pillar 226 may include the same material. For example, the first conductive pillar 224 and the second conductive pillar 226 may include copper. In embodiments, the first conductive pillar 224, the second conductive pillar 226, and the redistribution pattern 120 may include the same material. For example, the first conductive pillar 224, the second conductive pillar 226, and the redistribution pattern 120 may be formed of copper.

An insulating material layer 232 may be between the first semiconductor chip 210 of the semiconductor package 12 and the redistribution structure 100 of the semiconductor package 12 and may surround the conductive pillar 222. The insulating material layer 232 may include a first insulating material layer 234 and a second insulating material layer 236. The first insulating material layer 234 may surround a sidewall of the first conductive pillar 224, and the second insulating material layer 236 may surround a sidewall of the second conductive pillar 226. The first insulating material layer 234 and the second insulating material layer 236 may include materials which are substantially the same as or similar to materials of the first insulating material layer 233 and the second insulating material layer 235 described with reference to FIG. 3.

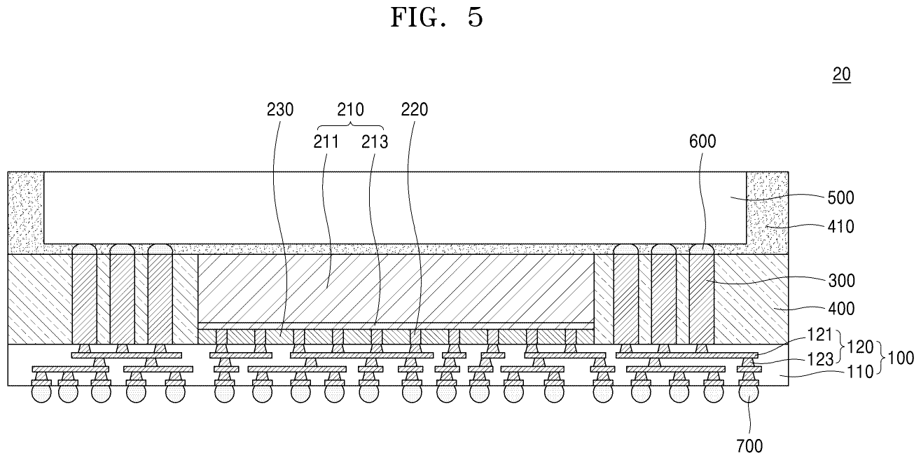

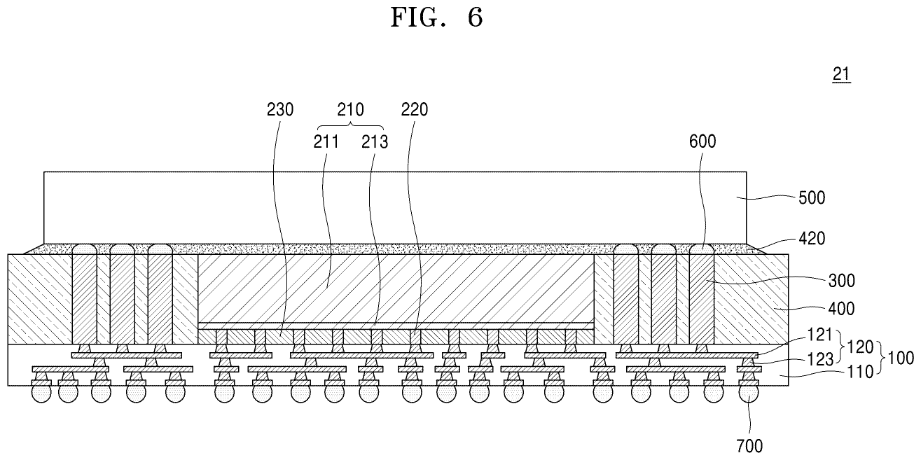

FIG. 5 is a cross-sectional view illustrating a semiconductor package 20 according to embodiments. FIG. 6 is a cross-sectional view illustrating a semiconductor package 21 according to embodiments. Configurations of a semiconductor package 20 illustrated in FIG. 5 and configurations of a semiconductor package 21 illustrated in FIG. 6 are similar to configurations of the semiconductor package 10 described with reference to FIGS. 1 and 2, and accordingly, the following will focus on differences therebetween.

Referring to FIG. 5, the semiconductor package 20 may include a redistribution structure 100, a first semiconductor chip 210, a first molding layer 400, conductive posts 300, a second semiconductor chip 500, and a second molding layer 410.

The second molding layer 410 may be on the first molding layer 400 and the first semiconductor chip 210. The second molding layer 410 may surround connection terminals 600 between the first molding layer 400 and the second semiconductor chip 500 and may cover a lower surface and side surfaces of the second semiconductor chip 500. A horizontal area of the second molding layer 410 may be less than or equal to a horizontal area of the first molding layer 400. An upper surface of the second molding layer 410 may be coplanar with an upper surface of the second semiconductor chip 500. However, embodiments of the present disclosure are not limited thereto. For example, the second molding layer 410 may cover the second semiconductor chip 500. The second molding layer 410 may include, for example, an epoxy molding compound. In embodiments, the first molding layer 400 and the second molding layer 410 may include the same material. For example, the first molding layer 400 and the second molding layer 410 may include an epoxy molding compound.

Referring to FIG. 6, the semiconductor package 21 may include a redistribution structure 100, a first semiconductor chip 210, a first molding layer 400, conductive posts 300, a second semiconductor chip 500, and an underfill layer 420.

The underfill layer 420 may be on the first molding layer 400 and the first semiconductor chip 210. The underfill layer 420 may surround connection terminals 600 between the first molding layer 400 and the second semiconductor chip 500 and may cover a lower surface of the second semiconductor chip 500. The underfill layer 420 may include, for example, a composite material of an epoxy-based resin and an inorganic filler, or an epoxy molding compound.

Unlike the structure illustrated in FIG. 6, the semiconductor package 21 may further include the second molding layer 410 (see FIG. 5). In this case, the second molding layer 410 may be on the first molding layer 400 and the first semiconductor chip 210 and may cover side surfaces of the second semiconductor chip 500 and the underfill layer 420.

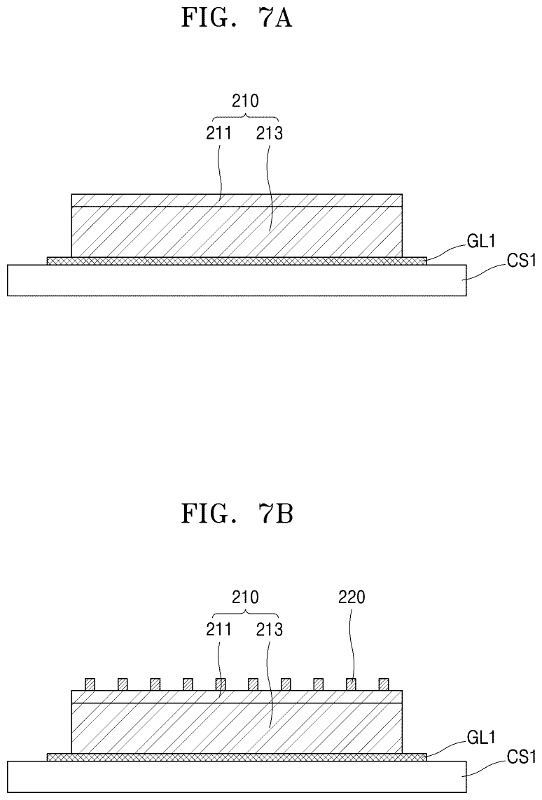

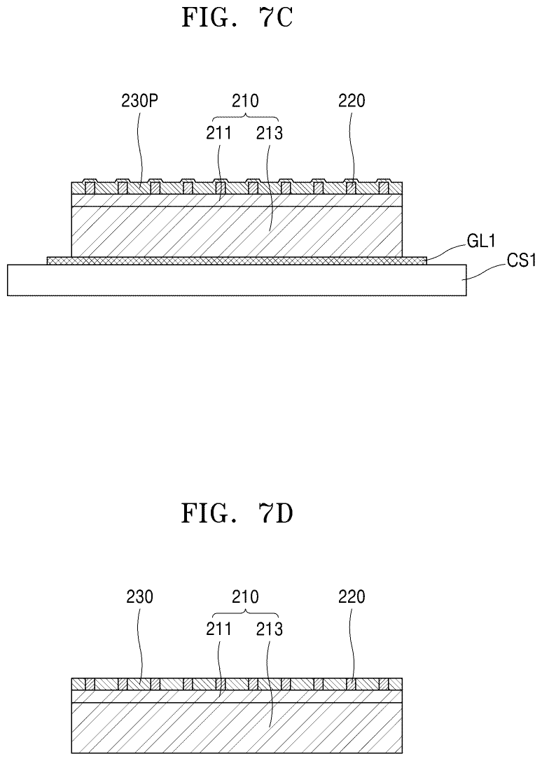

FIGS. 7A to 7D are cross-sectional views illustrating a method of manufacturing the semiconductor package 10, according to embodiments of the inventive concept.

Referring to FIG. 7A, a first adhesive film GL1 may be formed on a provided first support substrate CS1, and a first semiconductor chip 210 may be formed on the first support substrate CS1 on which the first adhesive film GL1 is formed. The first support substrate CS1 may be, for example, a semiconductor substrate, a glass substrate, a ceramic substrate, or a plastic substrate but is not limited thereto. The first adhesive film GL1 may be, for example, glue.

Referring to FIG. 7B, in the result of FIG. 7A, conductive pillars 220 may be formed on a wiring structure 213 of the first semiconductor chip 210. For example, the conductive pillars 220 may be formed by forming a seed layer on the wiring structure 213 and etching the seed layer by using a photoresist pattern formed on the seed layer. In another example, the conductive pillars 220 may also be formed by forming a seed layer on the wiring structure 213, forming a photoresist pattern on the seed layer, and performing a plating process by using the seed layer. The seed layer may include, for example, titanium and copper but is not limited thereto.

Referring to FIG. 7C, an insulating material layer 230p covering the wiring structure 213 and the conductive pillars 220 may be formed on the result of FIG. 7B. The insulating material layer 230p may be formed by, for example, a deposition process. The insulating material layer 230p may include, for example, at least one selected from SiO₂, SiC, SiON, SiOC, SiCN, SiN, and SiOCN. Parts of the insulating material layer 230p, which are formed on regions where the conductive pillars 220 are formed, may protrude more than the other parts of the insulating material layer 230p which are formed on regions where the conductive pillars 220 are not formed. Accordingly, one surface of the insulating material layer 230p, relatively far from the wiring structure 213, may not be flat.

Referring to FIG. 7D, a planarization process may be performed on the result of FIG. 7C. A part of the insulating material layer 230p may be removed according to the planarization process to form an insulating material layer 230, and one surface (e.g., an upper surface) of the insulating material layer 230, relatively far from the wiring structure 213, may be coplanar with surfaces (e.g., upper surfaces) of the conductive pillars 220 relatively far from the wiring structure 213. One surface (e.g., an upper surface) of the insulating material layer 230p relatively far from the wiring structure 213 may be exposed by the planarization process. The planarization process may be, for example, a mechanical polishing process or a chemical mechanical polishing process. Next, the first support substrate CS1 (see FIG. 7C) and the first adhesive film GL1 may be sequentially removed from the first semiconductor chip 210.

FIGS. 8A to 8P are cross-sectional views illustrating a method of manufacturing the semiconductor package 10, according to embodiments.

Referring to FIG. 8A, a second adhesive film GL2 may be formed on a second support substrate CS2. The second support substrate CS2 may be, for example, a semiconductor substrate, a glass substrate, a ceramic substrate, or a plastic substrate but is not limited thereto. The second adhesive film GL2 may be, for example, glue.

Referring to FIG. 8B, in the result of FIG. 8A, a seed layer SL may be formed on the second adhesive film GL2. In one embodiment, the seed layer SL may be formed by a deposition process. For example, the seed layer SL may be formed by physical vapor deposition (PVD), atomic layer deposition (ALD), or plasma enhanced chemical vapor deposition (PECVD). The seed layer SL may be, for example, a titanium/copper metal layer but is not limited thereto.

Referring to FIG. 8C, in the result of FIG. 8B, a first photoresist pattern PR1 may be formed on the seed layer SL. The first photoresist pattern PR1 may have a plurality of first openings PH1. The plurality of first openings PH1 may expose some parts of an upper surface of the seed layer SL which are in the central region. Positions of the plurality of first openings PH1 may be aligned with positions of the conductive pillars 220 described with reference to FIGS. 7A to 7D, and lengths of the plurality of first openings PH1 in a horizontal direction may be determined according to lengths of the conductive pillars 220 in the horizontal direction.

Referring to FIG. 8D, in the result of FIG. 8C, metal pads SP may be respectively formed in the plurality of first openings PH1. The metal pads SP may be formed from some parts of the seed layer SL exposed by the plurality of first openings PH1 through a plating process. In one embodiment, lengths of the metal pads SP in a vertical direction may be less than lengths of the plurality of first openings PH1 in the vertical direction.

Referring to FIG. 8E, the first photoresist pattern PR1 (refer to FIG. 8D) may be removed from the result of FIG. 8D. The first photoresist pattern PR1 may be removed by, for example, a strip process.

Referring to FIG. 8F, in the result of FIG. 8E, a second photoresist pattern PR2 may be formed on the seed layer SL. The second photoresist pattern PR2 may have a plurality of second openings PH2. The plurality of second openings PH2 may expose some parts of an edge region of an upper surface of the seed layer SL. Positions of the plurality of second openings PH2 may be aligned with positions of conductive posts 300 to be described below, and lengths of the plurality of second openings PH2 in the horizontal direction may be determined according to lengths of the conductive posts 300 in the horizontal direction. In embodiments, the second photoresist pattern PR2 may be a dry film photoresist.

Referring to FIG. 8G, in the result of FIG. 8F, conductive material layers 300p may be respectively formed in the plurality of second openings PH2. The conductive material layers 300p may be formed from some parts of the seed layer SL exposed by the plurality of second openings PH2 through a plating process. In one embodiment, lengths of the conductive material layers 300p in a vertical direction may be less than lengths of the plurality of second openings PH2 in the vertical direction. In embodiments, the conductive material layers 300p may each be formed of copper but is not limited thereto.

Referring to FIG. 8H, the second photoresist pattern PR2 (refer to FIG. 8G) may be removed from the result of FIG. 8G. The second photoresist pattern PR2 may be removed by, for example, a strip process. Next, the seed layer SL in a region where the metal pads SP and the conductive material layers 300p are not formed may be removed in the seed layer SL (refer to FIG. 8G).

Referring to FIG. 8I, in the result of FIG. 8H, the first semiconductor chip 210 may be bonded to the metal pads SP. First, connection terminals SB may be respectively formed on the metal pads SP. The connection terminals SB may each be, for example, a solder ball or a solder bump. Next, the first semiconductor chip 210 may be provided on the metal pads SP such that the conductive pillars 220 formed on a lower surface of the first semiconductor chip 210 respectively overlap the metal pads SP and the connection terminals SB in the vertical direction. Next, by performing a solder reflow process, the conductive pillars 220 may be respectively bonded to the metal pads SP respectively through the connection terminals SB. Since the conductive pillars 220 are respectively bonded to the metal pads SP through a solder reflow process, the conductive pillars 220 may be bonded to the metal pads SP in a self-aligned manner. Accordingly, the first semiconductor chip 210 may be accurately mounted in an intended position. In addition, because sidewalls of the conductive pillars 220 are completely covered by the insulating material layer 230 before the solder reflow process is performed, some of the connection terminals SB may not flow to the sidewalls of the conductive pillars 220 during the solder reflow process. Accordingly, an electrical short circuit between adjacent conductive pillars 220 which may occur due to the flow of the connection terminals SB on the sidewalls of the conductive pillars 220 may be prevented, and mutual insulation between adjacent ones of the conductive pillars 220 is well made, and thus, a pitch between the conductive pillars 220 may be reduced.

Referring to FIG. 8J, in the result of FIG. 8I, a first molding layer 400 may be formed on the second adhesive film GL2. The first molding layer 400 may cover the first semiconductor chip 210, the conductive material layers 300p, the insulating material layer 230, the metal pads SP, and the connection terminals SB. Next, a planarization process may be performed to remove a part of the first molding layer 400. As the planarization process is performed, one surface of each of the conductive material layers 300p and one surface of the first semiconductor chip 210 covered by the first molding layer 400 may be exposed. In addition, one surface of the first molding layer 400 on which the planarization process is performed, one surface of each of the exposed conductive material layers 300p, and one surface of the exposed first semiconductor chip 210 may be coplanar with each other.

Referring to FIG. 8K, in the result of FIG. 8J, a third support substrate CS3 on which a third adhesive film GL3 is formed may be coplanar with the one surface of the first molding layer 400, the one surface of each of the conductive material layers 300p, and the one surface of the first semiconductor chip 210 which are coplanar with each other, and the second support substrate CS2 (see FIG. 8J) may be removed from the second adhesive film GL2. The third support substrate CS3 may be, for example, a semiconductor substrate, a glass substrate, a ceramic substrate, or a plastic substrate but is not limited thereto. The third adhesive film GL3 may be, for example, glue.

Referring to FIG. 8L, in the result of FIG. 8K, the third support substrate CS3, the first semiconductor chip 210 attached thereto, the conductive material layers 300p, and the first molding layer 400 may be turned over. Next, a planarization process may be performed on a surface onto which the second adhesive film GL2 (see FIG. 8K) is attached, and thereby, the second adhesive film GL2, the connection terminals SB (see FIG. 8K), the metal pads SP (see FIG. 8K), a part of the first molding layer 400, and some of the conductive material layers 300p may be removed. The planarization process may be, for example, a mechanical polishing process or a chemical mechanical polishing process. As a part of the first molding layer 400 and some of the conductive material layers 300p are removed in the planarization process, one surface of the first molding layer 400 and one surface of each of the conductive material layers 300p may be coplanar with one surface of each of the conductive pillars 220. One surface of the first molding layer 400, one surface of each of the conductive material layers 300p, and one surface of each of the conductive pillars 220 may be exposed by the planarization process. The conductive material layers 300p partially removed by the planarization process may be referred to as a conductive post 300. The connection terminals SB and the metal pads SP may be completely removed by the planarization process.

Referring to FIG. 8M, in the result of FIG. 8L, a redistribution structure 100 may be formed on one surface of each of the exposed conductive posts 300 and one surface of each of the exposed conductive pillars 220. The redistribution structure 100 may be formed by repeatedly performing a lamination process and a plating process. For example, in the redistribution structure 100, redistribution lines 121 may be formed through a plating process, a redistribution insulating layer 110 covering the redistribution lines 121 may be formed through a lamination process, and via holes may be formed in the insulating layer 110, and thereafter, a process of forming redistribution vias 123 filling the via holes through the plating process may be repeatedly performed. As described above with reference to FIG. 8L, the connection terminals SB (see FIG. 8K) and the metal pads SP (see FIG. 8K) may be completely removed, and accordingly, the redistribution vias 123 of the redistribution structure 100 may be respectively in direct contact with the conductive pillars 220 to be metal-metal-bonded. Because the redistribution vias 123 are respectively metal-metal-bonded to the conductive pillars 220, a defect in electrical connection due to consumption of tin (Sn) of solder, which may occur during bonding using solder, may be prevented. Also, because the connection terminals SB (see FIG. 8K) are completely removed, a length of the first semiconductor chip 210 in the vertical direction may be increased. Accordingly, heat dissipation performance of the first semiconductor chip 210 may be improved.

After the redistribution structure 100 is formed, external connection terminals 700 may be formed on one surface of the redistribution structure 100 relatively far from the first semiconductor chip 210. The external connection terminals 700 may each be, for example, a solder ball or a solder bump.

Referring to FIG. 8N, in the result of FIG. 8M, a frame FF may be safely placed on the external connection terminals 700, and thereafter, the third support substrate CS3 (see FIG. 8M) may be removed from the third adhesive film GL3.

Referring to FIG. 8O, in the result of FIG. 8N, the first semiconductor chip 210, the redistribution structure 100, and the first molding layer 400, which are safely placed on the frame FF, may be turned over, and thereafter, the third adhesion film GL3 may be removed. Next, a surface from which the third adhesive film GL3 is removed may be cleaned, and connection terminals 600 may be respectively formed on the conductive posts 300.

Referring to FIG. 8P, in the result of FIG. 8O, a second semiconductor chip 500 may be bonded onto the connection terminals 600. The second semiconductor chip 500 may be electrically connected to the redistribution structure 100 through the connection terminals 600.

Thereafter, the frame FF may be removed from the result of FIG. 8P, and accordingly, the semiconductor package 10 illustrated in FIGS. 1 and 2 may be manufactured. Also, when the second molding layer 410 (see FIG. 5) covering the second semiconductor chip 500 is formed after the frame FF is removed, the semiconductor package 20 illustrated in FIG. 5 may be manufactured, and when the underfill layer 420 fills a space between the second semiconductor chip 500 and the connection terminals 600, the semiconductor package 21 illustrated in FIG. 6 may be manufactured.

While non-limiting example embodiments have been particularly shown and described, it will be understood that various changes in form and details may be made therein without departing from the spirit and scope of the present disclosure.

What is claimed is:

1. A method of manufacturing a semiconductor package, the method comprising:
forming a seed layer;
forming a first photoresist pattern on the seed layer;
forming a metal pad on the seed layer by using the first photoresist pattern;
forming a second photoresist pattern on the seed layer;
forming a conductive post on the seed layer by using the second photoresist pattern;
providing, on the metal pad, a first semiconductor chip on which a conductive pillar and an insulating material layer surrounding a sidewall of the conductive pillar are formed;
bonding the first semiconductor chip to the metal pad by using a connection terminal;
forming a first molding layer surrounding the first semiconductor chip;
removing the connection terminal and the metal pad; and
forming a redistribution structure connected to the conductive pillar.

2. The method of claim 1, wherein a lower surface of the conductive pillar is coplanar with a lower surface of the insulating material layer.

3. The method of claim 1, wherein the removing the connection terminal and the metal pad comprises performing chemical mechanical polishing or mechanical polishing.

4. The method of claim 1, wherein, after the removing the connection terminal and the metal pad, a lower surface of the conductive pillar, a lower surface of the first molding layer, and a lower surface of the conductive post are coplanar with one another.

5. The method of claim 1, wherein the second photoresist pattern includes a dry film photoresist.

6. The method of claim 1, wherein the redistribution structure is in contact with the conductive pillar and is metal-metal-bonded to the conductive pillar.

7. The method of claim 1, further comprising:
forming the connection terminal on the conductive post; and
connecting a second semiconductor chip to the connection terminal.

8. The method of claim 7, further comprising forming an underfill layer between the second semiconductor chip and the first semiconductor chip such that the underfill layer surrounds the connection terminal.

9. The method of claim 7, further comprising forming a second molding layer surrounding the second semiconductor chip.

10. A semiconductor package comprising:
a redistribution structure comprising redistribution lines and redistribution vias;
a first semiconductor chip on the redistribution structure;
a conductive post separated from the first semiconductor chip in a horizontal direction and on the redistribution structure;
a first molding layer surrounding the first semiconductor chip and the conductive post in the horizontal direction and on the redistribution structure;
conductive pillars on a lower surface of the first semiconductor chip, the conductive pillars respectively metal-metal-bonded to uppermost portions of some of the redistribution vias; and
an insulating material layer surrounding sidewalls of the conductive pillars.

11. The semiconductor package of claim 10, wherein lower surfaces of the conductive pillars are coplanar with a lower surface of the insulating material layer.

12. The semiconductor package of claim 10, wherein the insulating material layer comprises at least one from among SiO₂, SiC, SiON, SiOC, SiCN, SiN, and SiOCN.

13. The semiconductor package of claim 10, wherein a separation distance between a center of each of the some of the redistribution vias, that are metal-metal-bonded to the conductive pillars, and a center of a respective one of the conductive pillars is 1.0 μm or less.

14. The semiconductor package of claim 10, wherein the redistribution vias each have a tapered shape in which a length in the horizontal direction increases as a distance from the first semiconductor chip increases.

15. The semiconductor package of claim 10, further comprising:
a connection terminal on the conductive post; and
a second semiconductor chip on the first semiconductor chip and connected to the conductive post,
wherein the first semiconductor chip is a logic chip and the second semiconductor chip is a memory.

16. The semiconductor package of claim 15, further comprising an underfill layer between the first semiconductor chip and the second semiconductor chip and surrounding the connection terminal.

17. The semiconductor package of claim 15, further comprising a second molding layer on the first molding layer and surrounding the second semiconductor chip.

18. The semiconductor package of claim 10, wherein the conductive pillars comprise a plurality of layers.

19. The semiconductor package of claim 10, wherein the insulating material layer comprises a plurality of layers.

20. A method of manufacturing a semiconductor package, the method comprising:
forming a seed layer;
forming a first photoresist pattern on the seed layer;
forming a metal pad on the seed layer by using the first photoresist pattern;
forming a second photoresist pattern on the seed layer;
forming a conductive post on the seed layer by using the second photoresist pattern;
removing the seed layer and providing, on the metal pad, a first semiconductor chip including a lower surface on which a conductive pillar and an insulating material layer surrounding a sidewall of the conductive pillar are formed;
bonding the conductive pillar to the metal pad by performing a solder reflow process by using a connection terminal between the conductive pillar and the metal pad;
forming a first molding layer surrounding the first semiconductor chip;
planarizing an upper surface of the first molding layer;
removing the connection terminal and the metal pad by performing a planarization process; and
forming a redistribution structure that is metal-metal-bonded to the conductive pillar.
